(19) United States
(12) Patent Application Publication
(10) Pub. No.: US 2025/0283218 A1
(43) Pub. Date: Sep. 11, 2025

(54) SEMICONDUCTOR PROCESSING CHAMBER WITH ENHANCED PRESSURE TUNING

(71) Applicant: Applied Materials, Inc., Santa Clara, CA (US)

(72) Inventors: Muhannad Mustafa, Milpitas, CA (US); Sanjeev Baluja, Campbell, CA (US); Janisht Golcha, San Francisco, CA (US); Aditya Chuttar, Sunnyvale, CA (US)

(73) Assignee: Applied Materials, Inc., Santa Clara, CA (US)

(21) Appl. No.: 19/064,042

(22) Filed: Feb. 26, 2025

Related U.S. Application Data
(60) Provisional application No. 63/563,035, filed on Mar. 8, 2024.

(51) Int. Cl. C23C 16/44; C23C 16/52

(52) U.S. Cl. CPC C23C 16/4412; C23C 16/52

(57) ABSTRACT

Processing chamber exhaust systems and methods of controlling pressure within a processing chamber. The processing chamber exhaust systems includes a throttle valve disposed along an exhaust line extending from the processing chamber, a check valve upstream the throttle valve, and a purge line with a purge valve for supplying an inert gas to the exhaust line downstream the check valve and upstream the throttle valve. Methods of controlling pressure within the processing chamber comprise opening the throttle valve to varying extents and controlling the purge valve to control flow of inert gas to adjust pressure within the processing chamber.

### CROSS-REFERENCE TO RELATED APPLICATIONS

The present application claims priority to U.S. Provisional Application No. 63/563,035, filed Mar. 8, 2024, the entire disclosure of which is hereby incorporated by reference herein.

### TECHNICAL FIELD

Embodiments of the disclosure are directed to semiconductor manufacturing equipment. In particular, embodiments of the disclosure are directed to processing chamber exhaust systems and methods of controlling the pressure within a processing chamber.

### BACKGROUND

Thin films are generally fabricated in processing chambers selectively adapted for performing various deposition, etch, and thermal processes, among other processes, upon substrates, such as silicon (Si) wafers, gallium arsenide (GaAs) wafers, glass, sapphire, and the like. Various etch processes and deposition processes, including CVD and ALD, can be optimized by controlling the process conditions within the processing chamber. In particular, during a deposition process, the chemical reaction rate is strongly impacted by processing chamber pressure. As such, the ability to transition between and maintain precise target pressures within the processing chamber is critical to forming uniform deposition of thin films during semiconductor fabrication.

One method of controlling pressure within a processing chamber relies on pumping liners disposed within the processing chamber. However, pumping liners are a fixed hardware and do not provide in-situ modification of pumping conductance.

Another method of controlling pressure within a processing chamber uses vacuum pressure, in which an exhaust line extends from the processing chamber to a vacuum pump, and a throttle valve is disposed along the exhaust line. The throttle valve is opened and closed to varying degrees to adjust pressure within the processing chamber. While such systems provide adjustable pressure, they provide limited pressure tunability.

Accordingly, there is a need in the art for improved systems and methods that allow for a wider range of pressures at which semiconductor processing chambers can operate. There is a further need for improved systems and methods that provide a more precise transition between different pressures and maintain precise target pressures during various stages of a semiconductor fabrication process.

### SUMMARY

One or more embodiments of the disclosure are directed to a processing chamber exhaust system comprising an exhaust line that connects to a processing chamber; a throttle valve in fluid communication with the exhaust line and a fore line, the throttle valve defining a downstream end of the exhaust line and defining an upstream end of the fore line; a check valve positioned along the length of the exhaust line, the check valve configured to allow a flow of fluid from the processing chamber to pass through the check valve to the throttle valve downstream of the check valve; and a purge line connected to the exhaust line downstream of the check valve and upstream of the throttle valve, the purge line having a purge valve in fluid communication with the purge line to control a flow of purge gas through the purge line.

Another aspect of the disclosure is directed to a method of controlling the pressure in a processing chamber, the method comprising controlling a purge valve in fluid communication with a purge line connected to an exhaust line connected to the processing chamber, the purge line connected to the exhaust line downstream of a check valve and upstream of a throttle valve, the purge valve configured to control a flow of fluid through the purge line, wherein controlling the purge valve affects pressure within the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 is a schematic view illustrating a processing chamber exhaust system according to one or more embodiment;

FIG. 2 is a schematic view illustrating a processing chamber exhaust system according to one or more embodiments; and

FIG. 3 is a schematic view illustrating a processing chamber exhaust system according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon. A “substrate” refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

As used in this specification and the appended claims, the terms “reactive gas”, “process gas”, “precursor”, “reactant”, and the like, are used interchangeably to mean a gas that includes a species which is reactive in a deposition process. For example, a first “reactive gas” may simply adsorb onto the surface of a substrate and be available for further chemical reaction with a second reactive gas.

As used in this specification and the appended claims, the terms “upstream” and “downstream” refer to relative directions according to the flow of an exhaust gas stream from the interior of the processing chamber. Embodiments of the disclosure provide a processing chamber exhaust system and methods of controlling the pressure within a processing chamber.

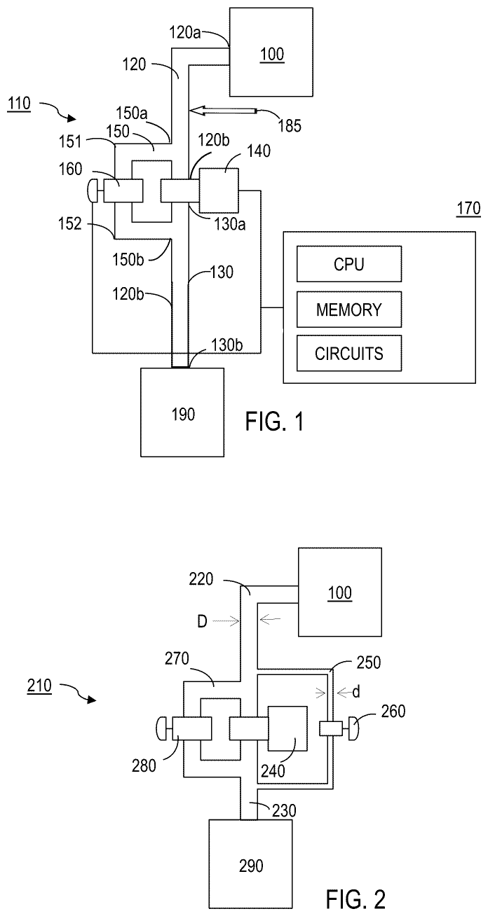

FIG. 1 illustrates a first embodiment of a processing chamber 100 in communication with an exhaust system 110. The exhaust system 110 includes an exhaust line 120 extending from the processing chamber 100 to fore line 130, and the exhaust line 120 has a length extending from where the exhaust line 120 connects to the processing chamber 100 at an upstream end 120a to where the exhaust line connects to a throttle valve 140 at a downstream end 120b. The throttle valve 140 is disposed along a length of the exhaust line 120 at the downstream end 120b. As depicted in FIG. 1, the throttle valve 140 defines a downstream end 120b of the exhaust line 120 and an upstream end 130a of the fore line 130 which extend to a downstream end 130b of the fore line. The fore line 130 has a length extending between the upstream end 130a and the downstream end 130b. As further illustrated in FIG. 1, a bypass line 150 branches off from the exhaust line 120 upstream the throttle valve 140 and reconnects with the fore line 130 downstream the throttle valve 140. The bypass line 150 has a length extending from where it branches off from the exhaust line at 120 at upstream end 150a to where it connects to the fore lines at downstream end150b. A bypass valve 160 is disposed along the bypass line 150. According to various embodiments, the bypass valve 160 is a pneumatically operated open/close valve disposed in parallel with the throttle valve 140

During use, the vacuum source 190 comprising a vacuum pump in connection with the fore line 130 is used to adjust and control the pressure of the processing chamber 100. The throttle valve 140 is opened and closed to varying degrees to increase and decrease vacuum supplied from the vacuum source, which adjusts the pressure within the processing chamber 100. Pressure within the processing chamber 100 can also be adjusted by opening and closing the bypass valve 160, which provides additional operational flexibility by diverting a portion of the gas exhausted from the processing chamber 100 through the bypass line 150.

As illustrated in FIG. 1, a controller 170 can further be provided. The controller 170 is independently connected to the throttle valve 140 and bypass valve 160 and is configured to open and close the throttle valve 140 and bypass valve 160 to adjust and control pressure in the processing chamber 100. One or more pressure monitors 185 can further be provided in connection with the processing chamber 100 and/or exhaust system 110 along the length of the exhaust line 120, and be in communication with the controller 170, which is configured to monitor, adjust, and maintain target pressures in the processing chamber 100. Based on the pressure readings from the one or more pressure monitors 185, the controller 170 suitably opens and/or closes one or more of the throttle valve 140 and bypass valve 160 to adjust pressure within the processing chamber 100. The one or more pressure monitors can be provided in connection with the processing chamber 100 and/or can be disposed within the exhaust system 110 (e.g., upstream the throttle valve 140, upstream the bypass valve 160, downstream the throttle valve 140, and/or downstream the bypass valve 160).

Generally, if a pressure in the exhaust line 120 is too low, the pressure in the processing chamber 100 is too high. To decrease pressure in the processing chamber 100 to the target pressure, the controller 170 will open the throttle valve 140 to a greater extent. If the pressure in the exhaust line 120 is too high, the pressure in the processing chamber 100 is too low. To increase pressure in the processing chamber 100 to the target pressure, the controller 170 can adjust the throttle valve 140 to partially close the valve and/or can open the bypass valve 160 to divert a portion of the exhaust flow through the bypass line 150. In some embodiments, the bypass line 150 can be provided with a smaller diameter and/or longer length than the exhaust line 120, and in order to increase pressure in the processing chamber 100, the throttle valve 140 can be completely closed and the bypass valve 160 can be opened to divert all of the exhaust flow through the bypass line 150. The bypass line is shown as having two bends, namely a first bend 151 and a second bend 152. The bypass line 150 can also comprise a configuration in which upstream end 150a to downstream end 150b there are multiple bends, twists and/or turns to achieve required pressure. While a first bend 151 and a second bend 152 are shown as right angles, these bends could be in the form of angled bends from 20 degrees to 90 degrees, or the bends could be in the form of curves such as parabolic curves or arcs.

FIG. 2 illustrates a second embodiment of a processing chamber 100 in communication with an exhaust system 210. The exhaust system 210 includes an exhaust line 220 extending from the processing chamber 200 to fore line 230. A throttle valve 240 is disposed along a length of the exhaust line 220, which as shown in FIG. 1 extends from an upstream end where the exhaust line connects to the processing chamber to a downstream end at the connection at the bypass valve to a fore line 230. As depicted in FIG. 2, the throttle valve 240 defines a downstream end of the exhaust line 220 and an upstream end of the fore line 230. As further illustrated in FIG. 1, a first bypass line 250 branches off from the exhaust line 220 upstream the throttle valve 240 and reconnects with the fore line 230 downstream the throttle valve 240. A first bypass valve 260 is disposed along the first bypass line 250. As further illustrated in FIG. 2, a second bypass line 270 branches off from the exhaust line 220 upstream the throttle valve 240 and downstream the position where the first bypass line 250 branches off from the exhaust line 220. The second bypass line 270 reconnects with the fore line 230 downstream the throttle valve 240. The fore line 230 has a length extending from an upstream end in connection to the throttle valve 240 to a downstream end where it connects to a vacuum source 290 as shown in FIG. 1. As illustrated in FIG. 2, according to some embodiments, the second bypass line 270 reconnects with the fore line 230 upstream the position where the first bypass line 250 reconnects with the fore line 230. A second bypass valve 280 is disposed along the second bypass line 270. According to various embodiments, the first bypass valve 260 and second bypass valve 280 are pneumatically operated open/close valves disposed in parallel with the throttle valve 240.

During use, the vacuum source 290 comprising a vacuum pump in connection with the fore line 230 is used to adjust and control the pressure of the processing chamber 100. The throttle valve 240 is opened and closed to varying degrees to increase and decrease vacuum supplied from the vacuum source, which adjusts the pressure within the processing chamber 100. Pressure within the processing chamber 100 can also be adjusted by opening and closing the first bypass valve 260 and/or the second bypass valve 280, which provides additional operational flexibility by diverting a portion of the gas exhausted from the processing chamber 100 through one or more of the first bypass line 250 and second bypass line 270. As illustrated in FIG. 2, the first bypass line 250 can be provided with a smaller diameter than the second bypass line 270, thus allowing for additional tuning and tunability of pressure within the processing chamber 100.

Similar to the embodiment illustrated in FIG. 1, a controller, which is not shown in FIG. 2, is configured to monitor, adjust, and maintain target pressures in the processing chamber 100. Likewise, as shown in FIG. 1 but not shown in FIG. 2, one or more pressure monitors can further be provided in connection with the processing chamber 100 and/or exhaust system 210 along the exhaust line 220, and the controller is in communication with the pressure monitor so that the controller can make adjustments to the pressure and maintain the target pressure. The controller is independently connected to the throttle valve 240, first bypass valve 260, and second bypass valve 280, and is configured to open and close the throttle valve 240, first bypass valve 260, and second bypass valve 280 to adjust and control pressure in the processing chamber 100. A controller. Based on the pressure readings from the one or more pressure monitors, the controller suitably opens and/or closes one or more of the throttle valve 240, first bypass valve 260, and second bypass valve 280 to adjust pressure within the processing chamber 100. The one or more pressure monitors can be provided in connection with the processing chamber 100 and/or can be disposed within the exhaust system 210 (e.g., upstream the throttle valve 240, upstream the first bypass valve 260, upstream the second bypass valve 280, downstream the throttle valve 240, downstream the first bypass valve 260, and/or downstream the second bypass valve 280).

Generally, the pressure in the exhaust line 220, and the pressure in the processing chamber 100 can be adjusted depending on the desired operation condition. To decrease pressure in the processing chamber 100 to the target pressure, the controller will open the throttle valve 240 to a greater extent. To increase pressure in the processing chamber 100 to the target pressure, the controller can open the throttle valve 240 to a lesser extent. The controller can further open the first bypass valve 260 and/or the second bypass valve 280 to divert a portion of the exhaust flow through the first bypass line 250 and/or second bypass line 270. In some embodiments, the throttle valve 240 can be completely closed and the first bypass valve 260 and/or second bypass valve 280 can be opened to divert all of the exhaust flow through the first bypass line 250 and/or second bypass line 270. The first bypass line 250 can be provided with a first diameter “D” and the second bypass line 270 can be provided with a second diameter “d” and opening of first bypass valve 260 and/or second bypass valve 280 is dependent upon the measured pressure in the exhaust line 220 and the target pressure in the processing chamber 100.

In other embodiments, the first bypass line 250 has a length extending from a junction 250a at the exhaust line 220 to a junction 250b at the fore line 230. The second bypass line 270 has a length extending from a junction 270a at the exhaust line 220 to a junction 270b at the fore line 230. In some embodiments, the length of first bypass line 250 and the length of the second bypass line 270 are different, and these respective lengths are varied the lengths of the to achieve flow conductance variations in the exhaust system 210.

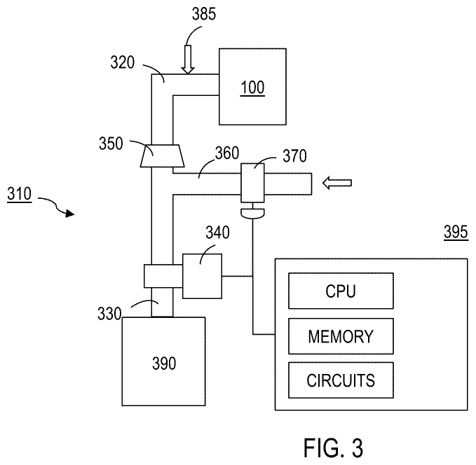

FIG. 3 illustrates a third embodiment of a processing chamber 100 in communication with an exhaust system 310. The exhaust system 310 includes an exhaust line 320 extending from the processing chamber 100 to a throttle valve 340 where the exhaust line connects to a fore line 330. A throttle valve 340 is disposed along a length of the exhaust line 320. The exhaust line 320 has a length extending from an upstream end connected to the processing chamber 100 to a connection at a downstream end at the throttle valve as shown in FIG. 1. The fore line 330 has a length extending from an upstream end at the connection to the throttle valve 340 to a downstream end connection to a vacuum source 390 comprising a vacuum pump, as shown in FIG. 1. As depicted in FIG. 3, the throttle valve 340 defines the downstream end of the exhaust line 320 and an upstream end of the fore line 330. A check valve 350 is further disposed along a length of the exhaust line 320 upstream the throttle valve 340. The check valve 350 is configured to allow one way flow from the processing chamber 100 downstream through the exhaust line 320 to the fore line 330. As illustrated in FIG. 3, a purge line 360 is connected to the exhaust line 320 downstream the check valve 350 and upstream the throttle valve 340. A purge valve 370 is disposed along the purge line 360. The purge line 360 is in fluid communication with an inert gas source (e.g., argon, hydrogen, nitrogen, oxygen, helium). According to various embodiments, the purge valve 370 is a pneumatically operated open/close valve.

While a single purge line 360 having a purge valve 370 is illustrated in connection with the exhaust line 320, two or more purge lines (not shown in FIG. 3) can be provided connected to the exhaust line 320 downstream from the check valve 350, each of the two or more purge lines having a purge valve (not shown) similar to the configuration of the purge valve 370. According to some embodiments, two or more purge lines connect to the exhaust line 320 at different distances upstream the throttle valve 340. According to other embodiments, the two or more purge lines connect to the exhaust line at substantially the same distance upstream of the throttle valve. Each of the two or more purge lines can be configured with different conductance to allow for a wider range of processing chamber 100 pressures.

During use, a vacuum source 390 including a vacuum pump in connection with the fore line 330 is used to adjust and control the pressure of the processing chamber 100. The throttle valve 340 is opened and closed to varying degrees to increase and decrease vacuum supplied from the vacuum source, which adjusts the pressure within the processing chamber 100. Pressure within the processing chamber 100 can also be adjusted by opening and closing the purge valve 370, which flows an inert gas through the purge line 360 and into the exhaust line 320. The check valve 350, which is disposed in the exhaust line 320 upstream the purge line 360 prevents flow of inert gas upstream into the processing chamber 100 and directs the inert gas flow downstream. As such, the purge line 360 can provide increased gas flow through the exhaust system 310, thus further fine tuning pressure within the processing chamber.

As further illustrated in FIG. 3 a controller 395 can further be provided. The controller 395 is independently connected to the throttle valve 340 and purge valve 370 and is configured to open and close the throttle valve 340 and purge valve 370 to adjust and control pressure in the processing chamber 100. The controller is in communication with a pressure monitor 385 connected to the exhaust line 320. One or more pressure monitors (not shown) can further be provided in connection with the processing chamber 100 and/or exhaust system 310 (e.g. within the exhaust line 320), and controller 395 for monitoring, adjusting, and maintaining target pressures in the processing chamber 100. Based on the pressure readings from the one or more pressure monitors, the controller 395 is configured to open and/or close one or more of the throttle valve 340 and purge valve 370 to adjust pressure within the processing chamber 100. The one or more pressure monitors can be provided in connection with the processing chamber 100 and/or can be disposed within the exhaust system 310 (e.g., upstream the throttle valve 340, upstream the purge valve 370, downstream the throttle valve 340, and/or downstream the purge valve 370).

Generally, a pressure in the exhaust line 320 and a pressure in the processing chamber 100 can be adjusted. To decrease pressure in the processing chamber 100 to the target pressure, the controller will open the throttle valve 340 to a greater amount to allow more flow to reduce the pressure. To increase pressure in the processing chamber 100 to the target pressure, the controller can reduce the opening in the throttle valve 340. The controller is further configured open the purge valve 370 to provide an additional flow of inert gas through the exhaust line, which will provide further tunability in pressure in the processing chamber 100.

Another aspect of the disclosure pertains to a non-transitory computer readable medium including instructions, that, when executed by a controller of a processing system, causes the processing system to perform operations of the methods described herein. In one embodiment, a non-transitory computer readable medium including instructions, that, when executed by a controller of a processing system, causes the processing system to perform operations of the methods described herein.

The disclosure, thus, provides processing chamber exhaust systems and methods of controlling the pressure within a processing chamber in which one or more of a check valve, bypass valves, and purge valve are provided in an exhaust line to adjust chamber pressures. The disclosure provides a modular approach to vary fore line conductance that allows for a wider range of pressures at which a semiconductor processing chamber can be operated. The disclosure further provides a wider range of operating pressures for a given chamber architecture. The disclosure advantageously eliminates the need to open the processing chamber and add or remove hardware to change the pressure range at which the processing chamber can operate.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A processing chamber exhaust system comprising:
an exhaust line that connects to a processing chamber;
a throttle valve in fluid communication with the exhaust line and a fore line, the throttle valve defining a downstream end of the exhaust line and defining an upstream end of the fore line;
a check valve positioned along a length of the exhaust line, the check valve configured to allow a flow of fluid from the processing chamber to pass through the check valve to the throttle valve downstream of the check valve; and
a purge line connected to the exhaust line downstream of the check valve and upstream of the throttle valve, the purge line having a purge valve in fluid communication with the purge line to control a flow of purge gas through the purge line.

2. The processing chamber exhaust system of claim 1, wherein the purge valve is a pneumatic valve.

3. The processing chamber exhaust system of claim 2, further comprising a pressure monitor within one or more of the processing chamber or the exhaust line, and a controller connected to the purge valve, the controller configured to open and close the purge valve in response to a measurement from the pressure monitor.

4. The processing chamber exhaust system of claim 1, wherein there are two or more purge lines, each purge line having a purge valve.

5. The processing chamber of claim 4, wherein the two or more purge lines connect to the exhaust line at different distances upstream of the throttle valve.

6. The processing chamber of claim 5, wherein each of the two or more purge lines have different conductance.

7. The processing chamber of claim 4, wherein the two or more purge lines connect to the exhaust line at substantially the same distance upstream of the throttle valve.

8. The processing chamber of claim 7, wherein each of the two or more purge lines have different conductance.

9. A method of controlling a pressure in a processing chamber, the method comprising:
controlling a purge valve in fluid communication with a purge line connected to an exhaust line connected to the processing chamber, the purge line connected to the exhaust line downstream of a check valve and upstream of a throttle valve, the purge valve configured to control a flow of fluid through the purge line, wherein controlling the purge valve affects pressure within the processing chamber.

10. The method of claim 9, further comprising controlling the throttle valve to control the pressure within the processing chamber.

11. The method of claim 10, wherein the purge valve is a pneumatic valve.

12. The method of claim 10, further comprising measuring a pressure in one or more of the processing chamber or exhaust line and controlling the purge valve in response to a pressure measurement.

13. The method of claim 10, wherein there are two or more purge lines, each purge line having a purge valve and connected to the exhaust line downstream of the check valve and upstream of the throttle valve.

14. The method of claim 13, wherein each of the purge lines connects to the exhaust line at different distances upstream of the throttle valve.

15. The method of claim 13, wherein each of the purge lines connects to the exhaust line at same distances upstream of the throttle valve.

16. The method of claim 13, further comprising controlling the purge valves of the two or more purge lines to affect pressure within the processing chamber.

17. The method of claim 13, wherein each of the purge lines have different conductance.
